(19) United States
(12) Patent Application Publication
(10) Pub. No.: US 2007/0051304 A1
(43) Pub. Date: Mar. 8, 2007

(54) Vacuum-coating machine with motor-driven rotary cathode

(76) Inventor: Andreas Sauer, Grossosteim (DE)

Correspondence Address: VAN DYKE, GARDNER, LINN AND BURKHART, LLP, 2851 CHARLEVOIX DRIVE, S.E., P.O. BOX 888695, GRAND RAPIDS, MI, 49588-8695, US

(21) Appl. No.: 11/501,286

(22) Filed: Aug. 9, 2006

(30) Foreign Application Priority Data
Aug. 10, 2005 (EP) 05 017 403.6

(51) Int. Cl. C23C 14/00

(52) U.S. Cl. 118/50

(57) ABSTRACT

In a vacuum-coating machine (1), the drive unit (6) is mounted compliantly to the chamber housing (3) by means of an elastic intermediate plate (14), such that said drive unit can follow a wobbling motion imposed by the rotary cathode (10), with the support bearing (19) of the free end of the rotary cathode (18) capable of being of a rigid design.

The present invention concerns a vacuum-coating machine with motor-driven rotary cathode and a device for compensating a wobbling motion of the rotary cathode, in accordance with the generic part of claim 1.

In vacuum-coating technology, increasing use is being made of rotating coating cathodes (rotary cathodes), one end of which is flange-mounted to a drive unit, usually at the chamber housing of the process chamber accommodating the rotary cathodes. The rotary cathodes may be arranged horizontally or vertically in the vacuum-coating machine. The first of these (horizontal vacuum-coating machines) are used, for example, for glass coatings, and the second (vertical vacuum-coating machines), for example, for display coatings. The rotary cathodes are generally designed as a tubular target rotating about the longitudinal axis with a permanent magnet system inside the tube. The magnetic field emanating from there permeates the target material, as a result of which the familiar magnetron effect occurs. The rotation leads to highly uniform wear of the tubular target, and so prolongs service lives and reduces costs. Furthermore, a cooling system may be accommodated inside the tube. Two design principles are generally distinguished for horizontally arranged rotary cathodes. In the first principle, the complete drive unit, including the power and coolant feed (media feed), is arranged at the lid of the vacuum-coating chamber, by means of so-called end blocks or bearing blocks at one end of a rotary cathode, as shown in patent U.S. Pat. No. 4,445,997. An improved embodiment in which the end blocks or bearing blocks are arranged outside the process chamber to facilitate media feed, is shown in DE 100 04 787 A1. Basically, this design principle proves to be awkward, however, when the rotary cathodes or tubular targets are changed, since the entire unit, including the chamber lid, has to be removed from the vacuum-coating machine. In the second design principle, the drive unit, including the media feed, is mounted to the chamber outer wall, a fact which generally simplifies handling. When the rotary cathode or the tubular target is changed, it, including the magnet and cooling system located inside the tube, is removed from the flange of the drive unit and, with the chamber lid open, lifted out of the vacuum-coating chamber. Machines of this type are shown, for example in U.S. Pat. No. 5,200,049.

Up to a certain tube length, the rotary cathode may be designed as a freely projecting, i.e. cantilever, design. Especially in the case of long rotary cathodes, however, the increasing weight moment load necessitates additional support by means of a support bearing, usually at the free end of the rotary cathode.

Two design principles may be distinguished for tubular targets. The tubular targets of the first principle are mechanically stable, thick-walled tubes. The tubular targets of the second principle are very thin-walled tubes in which the actual target material (such as Si, Zn, SiAl), is applied to a mechanically stable support tube, for example by casting, plasma spraying or thermal joining (bonding). A shared feature of the tubes of both design principles is that, due to the temperature warping introduced during manufacture, they have to a certain degree spatially curved tubular axes, which cannot be re-worked, for example, straightened, because the materials are hard, brittle and frangible. These curved tubular target axes (longitudinal axes of the tubular targets) cause a wobbling motion of double amplitude when the rotary cathode is firmly clamped on one side at the opposite free end of the rotary cathode. Given a maximum tube length of 4 m, deviations in tubular axis of 10 mm are no rarity, a fact which leads to a wobbling motion of +/−10 mm. To ensure adequate support in spite of this wobbling motion at the free end of the rotary cathode, mostly spring-mounted supports are used there that follow the wobbling motion and are able to damp them. Such a support is described, for example, in U.S. Pat. No. 5,620,577. The supporting force may be adjusted by pre-tensioning at least one spring.

The known solutions to the underlying problem, i.e. support for a wobbling rotary cathode, have various disadvantages, however. When tubular targets of different weights are used, the spring pre-loading of the support bearing must be adjusted to the respective weight of the tubular target. Further, when the tubular target describes a full rotation, the supporting force fluctuates by an amount calculated from the spring rate of the spring system and the wobbling deflection. Since the mass of the tubular target decreases during operation as a result of sputter erosion (down to as much as 20% of the original weight), the supporting force ideally must be readjusted during operation. The constantly changing conditions ultimately also lead to extreme bearing loads in the support bearing and thus to premature wear.

Attempts are therefore made to dimension the support bearing to the maximum loading case, a fact which in turn leads to large bearings and thus associated high costs. Patent EP 1 365 436 A2 describes a rotary cathode drive which already implements design measures for drive-side compensation of wobbling motions. This is effected by suspending the gear unit movably in an enclosing housing and via gearing play in the drive assembly. From a design point of view, limits are thus imposed on the degrees of freedom for compensating wobbling motions. Furthermore, retrofitting existing machines with such rotary-cathode drives proves to be disadvantageous as this can only be done at high design and financial outlay. The latter consideration basically concerns the construction of new machines as well, which becomes correspondingly more expensive.

The object of the invention is to provide a rotary-cathode bearing which, on one hand, can follow and damp the wobbling motion of the rotary cathode, but, on the other, does not require readjustment, and further facilitates simple changing of the rotary cathode or tubular target. At the same time, the solution to the problem should also be applicable to existing machines and comparatively inexpensive.

This object is achieved in accordance with the invention having the features of the characterizing part of claim 1. The features of the subsequent sub-claims indicate advantageous further developments.

The invention is based on the consideration of intercepting the wobbling motion imposed by the rotary cathode (more accurately by the tubular target) not on the side of the support bearing, but rather essentially on the drive side. To this end, the entire drive unit to which the rotary cathode is compliantly flange-mounted, that is to say movably in a defined measure, is mounted to the chamber housing, especially to a lateral chamber outer wall. This is effected by arranging an elastic intermediate plate at the connecting point (mounting flange) between drive unit and chamber housing, said intermediate plate being expediently formed from an elastomer and preferably by a thick rubber slab. With this elastic intermediate plate, the drive unit is now capable of executing the wobbling motion imposed by the rotary cathode, with the support bearing of the free rotary cathode end now capable of having a rigid design. Since, on account of the rigid design, weight moments no longer act upon the support bearing, but rather just the weight force equivalent to half the rotary-cathode mass, this support bearing can now have smaller overall dimensions overall, a fact which frees up construction space and saves on costs. Further, readjustment of a spring pre-load becomes superfluous.

Because the material of the intermediate plate is elastic, a vacuum seal is automatically obtained, with the result that further sealing measures for sealing the process chamber at this point are unnecessary or hitherto measures of sealing the drive side can be dispensed with.

The invention is therefore also of particular interest since existing vacuum-coating machines can be retrofitted cost effectively, with the existing drive units, including all their feed mechanisms (media feed), capable of being further used. For the construction of new machines, too, the design and financial outlay for implementing the invention are comparatively low.

By way of an initially unexpected advantage, it has furthermore emerged that the inclination angle of the rotary cathode relative to the chamber wall, which typically is in the region of 90°, can be selectively altered within a certain range of degrees on account of the elastic behavior of the intermediate plate.

A further advantage is that the intermediate plate markedly reduces vibrational transmission from the drive unit to the vacuum-coating chamber, a fact which increases production quality and contributes to noise reduction.

If the intermediate plate is formed from an electrically nonconducting material, it may simultaneously serve as an isolator between the chamber and the cathode potential. Other isolation measures, such as the installation of an isolation block, may thus be dispensed with.

Depending on the design of the intermediate plate, especially the mounting technology, longitudinal expansion of the rotary cathode, for example as a result of heating and cooling, can be compensated as well, a fact which hitherto had necessitated the use of additional design measures if high loads in the support bearing or in the drive unit were to be avoided. (The background to this paragraph is citation EP 1 365 436 A2)

The enclosed drawings are intended to describe a concrete embodiment of the invention in more detail. In it,

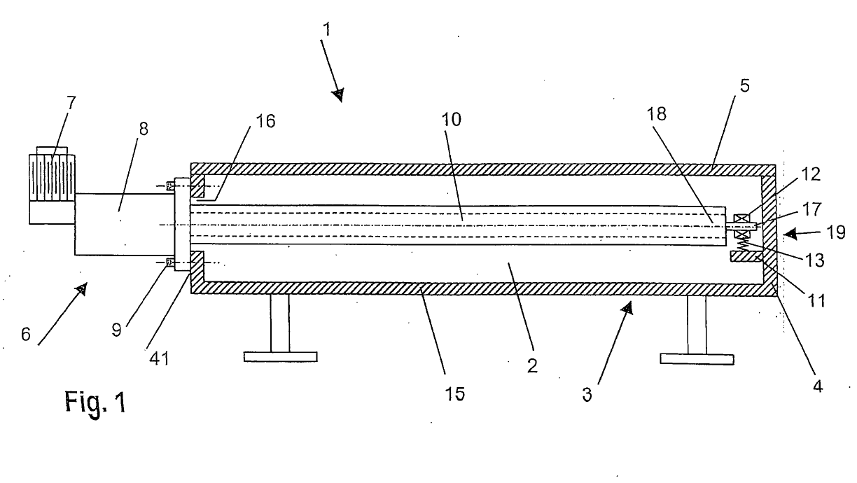

FIG. 1 a cross-sectional representation of a horizontal vacuum-coating machine with a rotary cathode of the prior art

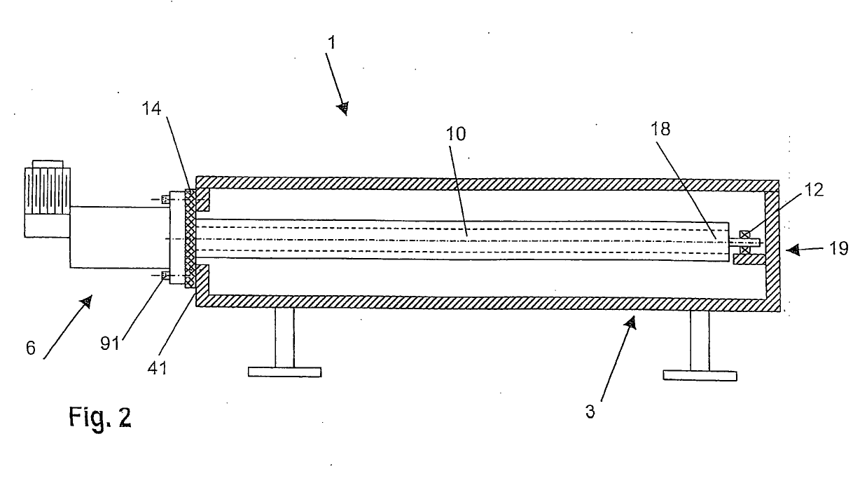

FIG. 2 is a cross-sectional representation of a horizontal vacuum-coating machine with the drive-unit suspension in accordance with the invention

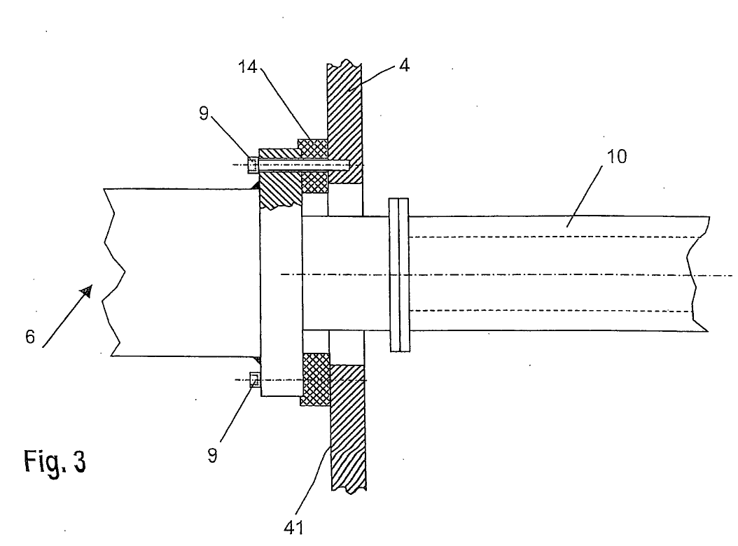

FIG. 3 a detailed view of the connecting point between drive unit and chamber wall in cross-section

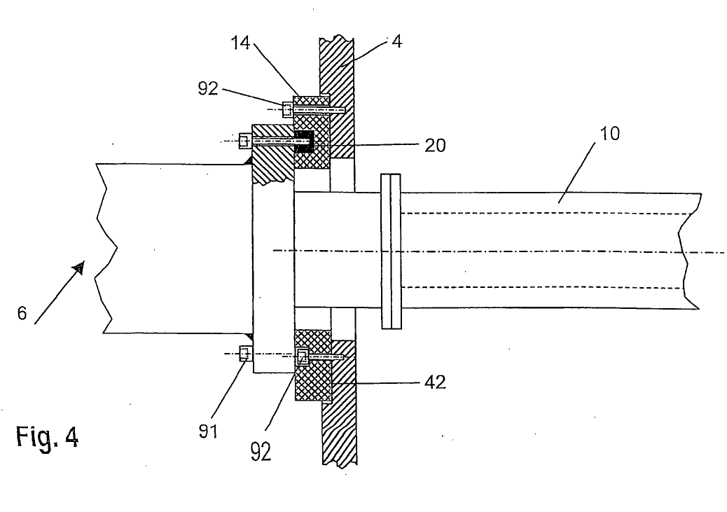

FIG. 4 a detailed view of the connecting point between drive unit and chamber wall in cross-section with an alternative connecting technology

FIG. 1 shows a horizontal vacuum-coating machine 1 in accordance with the prior art. A process chamber 2 is limited by lateral chamber walls 4, a chamber floor 15 and a chamber lid 5, which facilitates access to the process chamber for maintenance and repair work. Inside the process chamber 2 is arranged at least one rotary cathode 10, in this embodiment with a tubular target. The rotary cathode could equally have a solid design, however. Not shown are the usual prior-art fixtures installed inside the tube cathode, for example a magnet and/or cooling system and the like. For reasons of clarity, means of support and transport within the process chamber 2 for the work pieces to be processed are not shown either. These means are known to an expert skilled in the art, so that a description is superfluous. One end of the rotary cathode 10 is connected, preferably rigidly flange-mounted, through a wall opening 16 in the lateral chamber wall 4, to a drive unit 6. The drive unit 6 is mounted to the chamber outer wall 41, for example with fixing screws 9, and comprises a drive motor 7 and a gear/coupling block 8, with the latter also comprising the mounting on this side for the rotary cathode. Both the rotary movement and the media required for the process, such as coolants, are thus introduced or fed from the side into the drive-side of the process chamber. For changing the rotary cathodes 10, the rotary cathode is removed from the flange of the drive unit 6 and, along with all its fixtures, lifted upwards through the opened chamber lid 5 and out of the process chamber 2.

To keep the weight moment load that emanates from the rotary cathode on the drive unit 6 and its mounting means low, the free end 18 of the rotary cathode, i.e. the end opposite the flange, is supported by a support bearing 19. In the embodiment of FIG. 1, the rotary cathode 10 is to this end continued by a shaft journal 17, which is accommodated by a rolling bearing 12, with the rolling bearing 12 mounted to a support 11. In the embodiment shown, the support bearing 19 is arranged inside the process chamber 2, it is however also possible to effect the support outside the process chamber 2, for which purpose the rotary cathode 10 or a continued shaft journal 17 has to be fed through a corresponding opening in the lateral chamber wall 4, a fact which entails additional design outlay. As a consequence of production tolerances and manufacturing-related thermal warping of the tubular target, the rotary cathode has, to a certain degree, a spatially curved tubular axis, with several radii of curvature and curvature directions all capable of being present in a rotary cathode. As a consequence of the rigid mounting of the rotary cathode 10 to the drive unit 6, the free end of the rotary cathode 18 thus executes a multi-dimensional wobbling motion during rotation. In order to be able to follow this wobbling motion, the support bearing 19 has a spring system 13, with the embodiment in FIG. 1 not showing damping and pre-loading elements. Preloading and/or damping of the spring system 13 has to be manually readjusted to an extent depending on the rotary cathode 10 installed and on target material wear.

If the axis of the rotary cathode 10 is not at the correct angle relative to the chamber wall 4, for example at a 90° angle, the angle of inclination of the rotary cathode 10 may be altered relative to the chamber wall 4 by differentially tightening the fixing screws 9, i.e. by differentially compressing the intermediate plate 14. This is also especially of interest for the retrofitting of existing machines since, in this way, with the aid of a centering tool, the driven-shaft axis of the drive unit 6 can be aligned with the center of the support bearing 19 opposite. This also means that it is possible to align the drive unit 6 with the rotary-cathode axis. For reasons of clarity, the embodiment of FIG. 1 does not show means of isolation, for example in the form of an isolation block, which, as necessary, isolates the various electrical potentials between rotary cathode 10 and drive unit 6 on one side and the chamber housing on the other.

FIG. 2 shows a horizontal vacuum-coating machine with the invention's compliant suspension of the drive unit 6 at the chamber housing 3. The reference labels for the individual components are identical with those of FIG. 1. In accordance with the invention, the drive unit 6 does not make direct contact with the chamber outer wall 41, but rather indirectly via a compliant intermediate plate 14, which has elastic material properties. The intermediate plate 14 here has, for example, the shape of an annular disk. As a consequence of the compliant suspension effected by the intermediate plate 14, the drive unit 6 flange-mounted to the rotary cathode 10 can now follow the wobbling motion of the rotary cathode, so that the support for the free end of the rotary cathode 18 may be executed as a rigid support. This thus obviates the need for re-adjustment or manual re-setting of a spring system in the support bearing 19. As a consequence of the lower moment and tensile loading on the roller bearing 12, the latter can now have smaller dimensions.

FIG. 3 shows a simple and cost-effective technology for mounting the drive unit 6 to the chamber outer wall 41 using an elastic intermediate plate 14. The drive unit 6 is mounted here to the chamber wall 4 by means of fixing screws 9, with the screw shafts extending right through via drilled holes in the drive unit 6 and the intermediate plate 14, and the screw threads engaging with corresponding counter-threads in the chamber wall 4. The drive unit 6 thus does not make direct contact with the chamber outer wall 41, but rather via an elastically compliant intermediate plate 14, as already described above. On account of the non-rigid connection, the drive unit 6 possesses a certain degree of mobility relative to the chamber wall 4. Should electrical isolation of the various potentials of chamber housing 3 and drive unit 6 be necessary, so-called isolation sleeves for the screws 9 (not shown) may be used.

FIG. 4 shows an alternative technology for mounting drive unit 6 to the chamber wall 4. An advantage of this more elaborate mounting technology lies in the extended degrees of movement of drive unit 6 relative to the chamber wall 4. The intermediate plate 14 is mounted here by screws 92 to the lateral chamber wall 4 via drilled through-holes. To an extent depending on the arrangement of the screws 92, it may be necessary to provide counter-sinking for the screw heads. The drive unit 6 is mounted to the intermediate plate 14 by means of fixing screws 91. For this, it may be necessary to reinforce the threads inside the intermediate plate 14, for example by means of metallic thread inserts. The design idea here is that the means of mounting do not create a rigid connection between drive unit 6 and chamber wall 4. A further advantage of this mounting technology is that, on account of the underlying principle, the various potentials of chamber housing 3 and drive unit 6 are electrically isolated.

In a further embodiment not shown, mounting bolts pass from the drive unit 6 through the intermediate plate 14 and are secured to the back side of intermediate plate 14, i.e. the side facing the chamber wall 4, for example with nuts, for which purpose the design must provide appropriate space. Other connecting technologies and methods are also conceivable, however.

In order that intermediate plate 14 may also produce a vacuum seal between chamber wall 4 and drive unit 6, the chamber outer wall 41 must be reworked at the corresponding point (surface section) in order that a surface of sealing-surface quality may be obtained, with the necessary surface quality critically depending on the intermediate plate 14 employed. In the embodiment shown in FIG. 4, therefore, a recessed wall area (cutout, recess) 42 is shown which corresponds to such a reworked surface section. It is also conceivable, however, for the surface section to be formed not as a recessed wall area, but as a projecting wall area. In the case of a recessed wall area 42, the advantage is that of simplified assembly.

The intermediate plate 14 is formed from an elastomer, preferably from a rubber material, especially from a natural rubber or silicone. The Shore hardness is 50° minimum and 80° maximum. A range of 60° to 70° Shore hardness is preferred. It goes without saying that such materials are electrically isolating. Materials for the intermediate plate 14 are obtainable on the market as semi-finished goods of the most diverse properties.

The idea of the invention is not limited to horizontal vacuum-coating machines, it is therefore also possible for an expert skilled in the art to implement it in a vertical vacuum-coating machine in which the free ends of the cathodes are also supported. It is equally conceivable for the features of the various embodiments described to be combined.

### LIST OF TERMS

1 Vacuum-coating machine
2 Process chamber
3 Chamber housing
4 Chamber wall
5 Chamber lid
6 Drive unit
7 Motor
8 Gear/coupling block including bearing
9 Fixing screws (drive unit/chamber wall)
10 Rotary cathode (tubular target)
11 Support
12 Rolling bearing
13 Spring (with pre-loading and damping)
14 Intermediate plate
15 Chamber floor
16 Wall opening
17 Shaft journal
18 Free end of rotary cathode
19 Support bearing
20 Metallic thread insert
41 Chamber outer wall
42 Cutout, recess
91 Fixing screws (drive unit/intermediate plate)
92 Fixing screws (intermediate plate/chamber wall)

1-10. (canceled)

11. A vacuum-coating machine comprising:
at least one process chamber with a chamber housing;
at least one rotary cathode supported relative to the chamber housing, the rotary cathode driven by a drive unit; and
wherein the drive unit is arranged by a compliant suppression relative to the chamber housing.

12. The vacuum-coating machine in accordance with claim 11, wherein the compliant suspension of the drive unit includes an intermediate plate arranged between the chamber housing and the drive unit.

13. The vacuum-coating machine in accordance with claim 12 wherein the drive unit is mounted to the chamber wall by fasteners which extend through drilled holes in the drive unit and the intermediate plate.

14. The vacuum-coating machine in accordance with claim 12, wherein the intermediate plate is mounted only to the chamber housing and the drive unit is mounted only to the intermediate plate.

15. The vacuum-coating machine in accordance with claim 11, wherein the chamber housing includes a wall opening, the drive assembly having a drive assembly fed with a diameter, the rotary cathode having a wobbling deflection, the wall opening being at least that of the diameter of the drive assembly fed plus twice the wobbling deflection of the rotary cathode.

16. The vacuum-coating machine in accordance with claim 12 wherein the intermediate plate is formed from an elastomer.

17. The vacuum-coating machine in accordance with claim 17, wherein the elastomer comprises a rubber material, especially from a natural rubber or silicone.

18. The vacuum-coating machine in accordance with claim 17, wherein the rubber material comprises a natural rubber or silicone.

19. The vacuum-coating machine in accordance with claim 16, wherein the elastomer has a Shore hardness of 50° minimum and 80° maximum Shore hardness.

20. The vacuum-coating machine in accordance with claim 19, wherein the Shore hardness is in a range of 60° to 70° Shore hardness.

21. The vacuum-coating machine in accordance with claim 12 wherein the intermediate plate is formed from an electrically nonconducting material.

22. The vacuum-coating machine in accordance with claim 11, wherein the rotary cathode is supported by a support bearing at a free end of the rotary cathode.

23. The vacuum-coating machine in accordance with claim 22, wherein the support bearing comprises a rigid bearing.

24. The vacuum-coating machine in accordance with claim 11, wherein the chamber housing has an outer wall, the outer wall having a surface section for contact with the intermediate plate.

25. The vacuum-coating machine in accordance with claim 24, wherein the surface section includes a cutout or recess.

26. A vacuum-coating machine comprising:
a chamber housing;
at least one rotary cathode, the rotary cathode supported relative to the housing, the housing having a chamber wall; and
a drive unit driving the rotary cathode through the chamber wall, the drive unit mounted to the chamber wall with a non-rigid connection wherein the drive unit has at least one degree of freedom of movement relative to the chamber wall wherein the drive unit can follow wobbling motion of the rotary cathode.

27. The vacuum-coating machine according to claim 26, wherein the drive unit is mounted to the chamber wall by an intermediate member, the intermediate member formed from an elastomer material.

28. The vacuum-coating machine according to claim 27, wherein the drive unit is mounted to the intermediate member and the intermediate member is mounted to the chamber wall wherein the drive unit has at least two degrees of freedom of movement relative to the chamber wall.

29. The vacuum-coating machine according to claim 27, further comprising a support, wherein the drive unit is coupled to one end of the rotary cathode, the support providing a rigid support for the other end of the rotary cathode.

30. The vacuum-coating machine according to claim 29, wherein the chamber wall has an opening, the rotary cathode having a range of wobbling motion, the drive unit driving the rotary cathode through the opening, wherein the opening is sized greater than the range of wobbling motion of the rotary cathode.
